(19) United States
(12) Patent Application Publication
(10) Pub. No.: US 2007/0029650 A1
(43) Pub. Date: Feb. 8, 2007

(54) Semiconductor package and package stacking structure and method using the same

(76) Inventors: Won-Chul Lim, Chungcheongnam-do (KR); Sang-Yeop Lee, Chungcheongnam-do (KR)

Correspondence Address: MARGER JOHNSON & MCCOLLOM, P.C., 210 SW MORRISON STREET, SUITE 400, PORTLAND, OR, 97204, US

(21) Appl. No.: 11/361,729

(22) Filed: Feb. 23, 2006

(30) Foreign Application Priority Data
Aug. 8, 2005 (KR) 2005-72387

(51) Int. Cl. H01L 23/495

(52) U.S. Cl. 257/666

(57) ABSTRACT

A semiconductor package presents Z-shaped outer leads. The outer leads have a first portion located near an upper surface of a package body, a second portion, and a third portion located near a lower surface of a package body. A second similar semiconductor package may be stacked on the first semiconductor package with the third portion of the second semiconductor package located on and electrically connected to the first portion of the first semiconductor package. In each of the first and second semiconductor packages, a distance between the bottom surface of the third portion of the outer lead and the lower surface of a package body may be greater than a distance between the top surface of the first portion of the outer lead and the upper surface of the package body.

### CROSS REFERENCE TO RELATED APPLICATIONS

This U.S. non-provisional application claims benefit of priority under 35 U.S.C. § 119 from Korean Patent Application No. 2005-72387, filed on Aug. 8, 2005, the entire contents of which are incorporated herein by reference.

### BACKGROUND

1. Field of the Invention

The present invention relates to a semiconductor package and a package stacking technique, and, more particularly, to a leadframe-based semiconductor package and package stacking structure and method using the leadframe-based semiconductor package.

2. Description of the Related Art

The electronic industry is continually seeking methods, techniques and designs that will result in the manufacture of electronic products that are smaller, lighter, faster, cost effective, and more efficient with multiple functions in improved overall performance. One of the methods used to attain such goals is a chip scale packaging technique, e.g., stacking individual semiconductor chips. The chip scale packaging technique may provide chip scale packages or chip size packages (CSPs).

Semiconductor packages that are lighter, smaller and thinner, and include a great capacity of semiconductor chips continue to be desirable. To increase the capacity of semiconductor chips while decreasing package size, certain technologies have arranged cells more densely in a limited area of a semiconductor chip. One solution has been 3-D type semiconductor packaging technologies based on stacking semiconductor chips or semiconductor packages.

Examples of 3-D stack chip packages include a package having a plurality of semiconductor chips stacked on each other, thereby achieving denser, more compact semiconductor packages. Unfortunately, 3-D type semiconductor packaging technologies based on chip stacking can negatively influence production rates. Individual chip operation is typically not tested until after placement in a package. Thus, faulty chips can dramatically impact production rates because a single faulty chip among a stack of packaged semiconductor chips can irreparably fault the whole stack or package of semiconductor chips.

One solution to the faulty stack problem has been to stack validated packages instead of individual chips. Although a stack of packages is thicker than a stack of chips, since each chip includes its own package, a stack of packages has the advantage that each package may be individually validated, thus avoiding the reliability and production rate problems associated with chip stacking.

A conventional package stacking technique has been studied on mechanical and electrical connections of individual packages. Various package stacking structures and methods have been suggested. Although prior art arrangements are generally thought to be acceptable, they are not without shortcomings. For example, the prior art arrangements require leads suitable for a package stacking structure. As a result, the individual packages used in the package stacking structure may not be used independently. The leads may not be feasibly produced by automation, thereby resulting in uneven or unpredictable quality of lead connection. An additional bonding member for an electrical connection of leads may cause a complicated package stacking process and an increase of manufacturing cost. Further, leads should be processed to establish an electrical connection subsequent to a package characteristic or validation test.

### SUMMARY

Example embodiments of the present invention provide a semiconductor stacking structure and method offering simple, reliable, stable, easy, and automated manufacturing at a desirable manufacturing cost. Embodiments of the present invention may provide a semiconductor package useful in a stack of packages or independently mountable.

According to example embodiments of the present invention, a semiconductor package, having a first surface and a second surface opposite thereto, includes outer leads each having a proximal portion, an intermediate portion, and a distal portion. Each proximal portion is substantially parallel to the associated distal portion. Each intermediate portion is in non-parallel relation to the associated proximal and distal portions. Each proximal portion is intermediate the first surface the second surface of the associated semiconductor package and each distal portion lies beyond the second surface. Such semiconductor packages may be stacked with the proximal portions of one package resting upon and electrically coupled to the distal portions of a second package. Such outer lead arrangement allows package testing prior to package stacking, allows a stack of such packages to mount at the lowermost set of outer leads, and allows an individual package to mount at its outer leads.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1A is a schematic cross-sectional view of an example of a semiconductor package in accordance with an example embodiment of the present invention.

FIG. 1B is a schematic cross-sectional view of another example of a semiconductor package in accordance with an example embodiment of the present invention.

FIG. 2 is a schematic cross-sectional view of a semiconductor package in accordance with another example embodiment of the present invention.

FIG. 3 is a partial cross-sectional view of a package stacking structure in accordance with an example embodiment of the present invention.

FIG. 4 is a partial cross-sectional view of a package stacking structure in accordance with another example embodiment of the present invention.

FIG. 5 is a perspective view of a package stacking method in accordance with an example embodiment of the present invention.

FIGS. 6A and 6B are perspective views of a package stacking method in accordance with another example embodiment of the present invention.

FIGS. 7A and 7B are perspective views of a package stacking method in accordance with another example embodiment of the present invention.

FIGS. 8A and 8B are perspective views of a package stacking method in accordance with another example embodiment of the present invention.

The drawings are provided for illustrative purposes only and are not necessarily drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example, non-limiting embodiments of the invention.

### DETAILED DESCRIPTION

Example, non-limiting embodiments of the present invention will be described more fully with reference to the accompanying drawings. This invention may, however, be embodied in many different forms and should not be construed as limited to the particular example embodiments set forth herein. Rather, the disclosed embodiments are provided to make this disclosure thorough and complete, and to fully convey the scope of the invention to those skilled in the art. The principles and features of this invention, therefore, may be employed in varied and numerous embodiments without departing from the scope of the invention.

Semiconductor Package

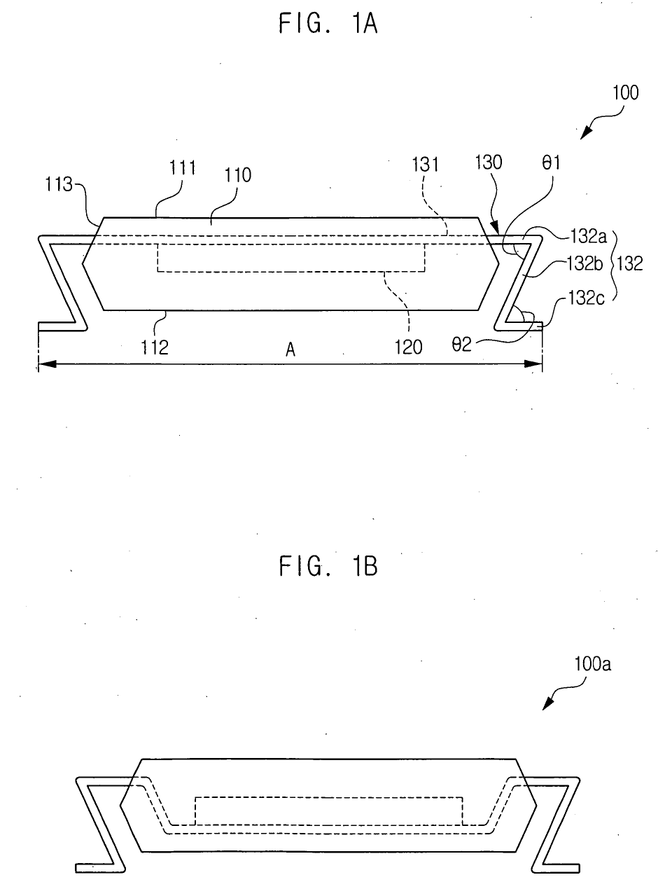

FIG. 1A is a schematic cross-sectional view of an example of a semiconductor package 100 in accordance with an example embodiment of the present invention.

Referring to FIG. 1A, the semiconductor package 100 is a leadframe-based semiconductor package, for example a typical thin small outline package (TSOP). The semiconductor package 100 may include a package body 110, an integrated circuit (IC) chip 120, and a leadframe 130.

The package body 110 may be from a mold resin, and have an upper surface 111, a lower surface 112, and side surfaces 113 connecting the upper surface 111 to the lower surface 112. As used herein the terms “upper”, “top”, “lower”, and “bottom” shall be in reference to the view of the various figures and components as presented in the drawings, it being understood that the actual relative orientation of a given device and its components in use or manufacture may differ. The IC chip 120 may be embedded in the package body 110. The package body 110 may protect the IC chip 120 from the external environment. The IC chip 120 may be a memory device chip, for example a NAND flash memory. However, the IC chip 120 may be not limited in this regard.

The leadframe 130 may include a plurality of leads including inner leads 131 and outer leads 132. The inner leads 131 may be located inside the package body 110, and the outer leads 132 may be located outside the package body 110. The inner leads 131 may be mechanically and electrically connected to the IC chip 120.

The inner leads 131 may have variations and/or modifications in respect to their types, configurations, arrangements, locations relative to the IC chip 120, and mechanical or electrical connection methods. Since variations and/or modifications of the inner leads 131 are dispensable to an understanding of the present invention, further detailed description thereof is omitted hereafter.

FIG. 1B is a cross-sectional view of another example of the semiconductor package 100, illustrating a semiconductor package 100a having a modified internal structure. The semiconductor package 100 may be not limited to a specific structure.

Returning to FIG. 1A, the semiconductor package 100 may be characterized by the outer leads 132 of the leadframe 130. The outer leads 132 may be formed integrally with the inner leads 131 and extend from the package body 110. The outer lead 132 may have a proximal or first portion 132a, an intermediate or second portion 132b and a distal or third portion 132c. In this particular embodiment, the portions 132a and 132c are generally in parallel and vertically aligned relation with the portion 132b in coupling non-parallel relation.

The first portion 132a may be provided near the upper surface 111 of the package body 110, connected to the inner lead 131 and may be located lower than the upper surface 111 of the package body 110, i.e., intermediate a plane containing the upper surface 111 and a plane containing the lower surface 112. The first portion 132a may be parallel to the upper surface 111 of the package body 110. The third portion 132c may be parallel to the first portion 132a and may be located lower than the lower surface 112 of the package body 110, i.e., located beyond a plane containing the lower surface 112 in a direction from the upper surface 111 toward the lower surface 112.

The second portion 132b may connect the first portion 132a to the third portion 132c, and may be at an angle of about 90° or less to each of the first portion 132a and the third portion 132c. The first portion 132a and the second portion 132b may form an angle θ1, and the second portion 132b and the third portion 132c may form an angle θ2. Each of angles θ1 and θ2 may be about 90° or less. As such, the outer lead 132 may be formed in a Z-shape. The use of the Z-shaped outer lead 132 need not influence the total width (A) of the semiconductor package 100 and of an associated package mounting area.

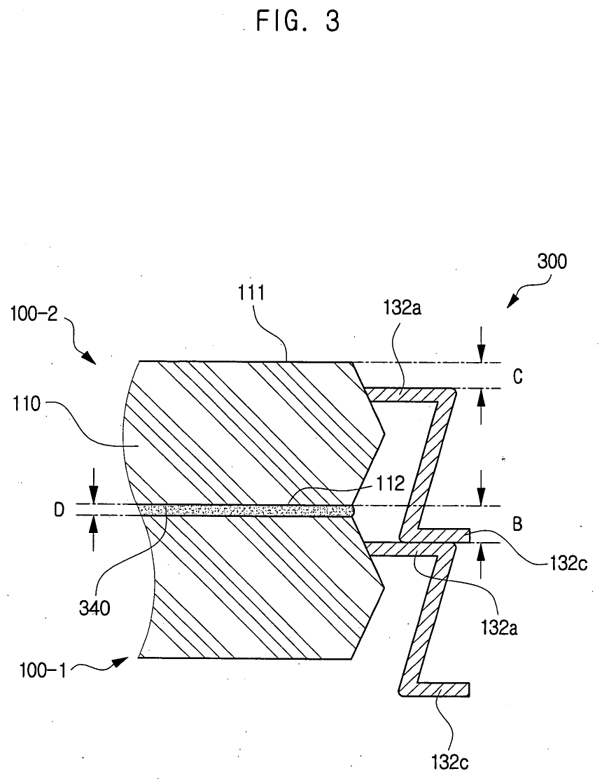

The distance between the bottom-facing surface of the third portion 132c and the lower surface 112 of the package body 110 may be greater than the distance between the top-facing surface of the first portion 132a and the upper surface 111 of the package body 110 as described more fully in reference to FIG. 3.

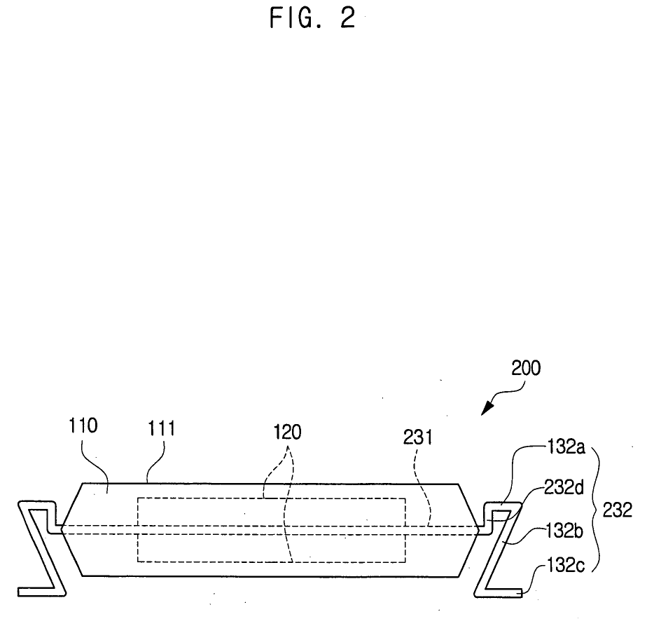

FIG. 2 is a schematic cross-sectional view of a semiconductor package 200 in accordance with another example embodiment of the present invention.

Referring to FIG. 2, the semiconductor package 200 may have a similar structure as the semiconductor package 100 except for having modified outer leads 232. Outer leads 232 of this example embodiment may further have a fourth portion 232d formed between a first portion 132a and an inner lead 231. When the inner lead 231 is not arranged sufficiently near the upper surface 111 of the package body 110, the fourth portion 232d may connect the inner lead 231 to the first portion 232a of the outer lead 232. Addition of the fourth portion 232d need not influence the overall generally Z-shaped outer lead 232 nor its ability to offer packaging stacking or package mounting as described hereafter in reference to semiconductor package 100. In other words, the semiconductor package 200 may be stacked or mounted in fashion similar to that hereafter shown for package 100. IC chips 120 may be provided on and beneath the inner lead 231. Although this example embodiment shows two IC chips 120, the IC chips 120 may include one as shown in FIGS. 1 and 1A, or three or more.

Package Stacking Structure

FIG. 3 is a partial cross-sectional view of a package stacking structure 300 in accordance with yet another example embodiment of the present invention.

Referring to FIG. 3, the package stacking structure 300 may comprise a first semiconductor package 100-1 and a second semiconductor package 100-2 provided in stacked relation on the first semiconductor package 100-1. Each of the first and second semiconductor packages 100-1 and 100-2 may have similar structure, e.g. as the semiconductor package 100 or the semiconductor package 200. Although this example embodiment shows the package stacking structure 300 using the semiconductor package 100, the package stacking structure 300 may be not limited to the use of a specific semiconductor package.

A third portion 132c of the second semiconductor package 100-2 may be located on a first portion 132a of the first semiconductor package 100-1. In each of the first and second semiconductor packages 100-1 and 100-2, the distance (B) between the bottom-facing surface of the third portion 132c and a lower surface 112 of a package body 110 may be greater than the distance (C) between the top-facing surface of the first portion 132a and an upper surface 111 of the package body 110.

The package stacking structure 300 may further include an adhesive layer 340 provided between the package body 110 of the first semiconductor package 100-1 and the package body 110 of the second semiconductor package 100-2. In each of the first and second semiconductor packages 100-1 and 100-2, the distance (B) between the lower surface 112 of the package body 110 and the bottom-facing surface of the third portion 132c may be equal to or greater than the sum of the distance (C), e.g., between the upper surface 111 of the package body 110 and the top-facing surface of the first portion 132a, and the thickness (D), e.g., of the adhesive layer 340.

Therefore, the third portion 132c of the second semiconductor package 100-2 may be mechanically and electrically coupled to the first portion 132a of the first semiconductor package 100-1 while accommodating the adhesive layer 340 between the packages 100-1 and 100-2.

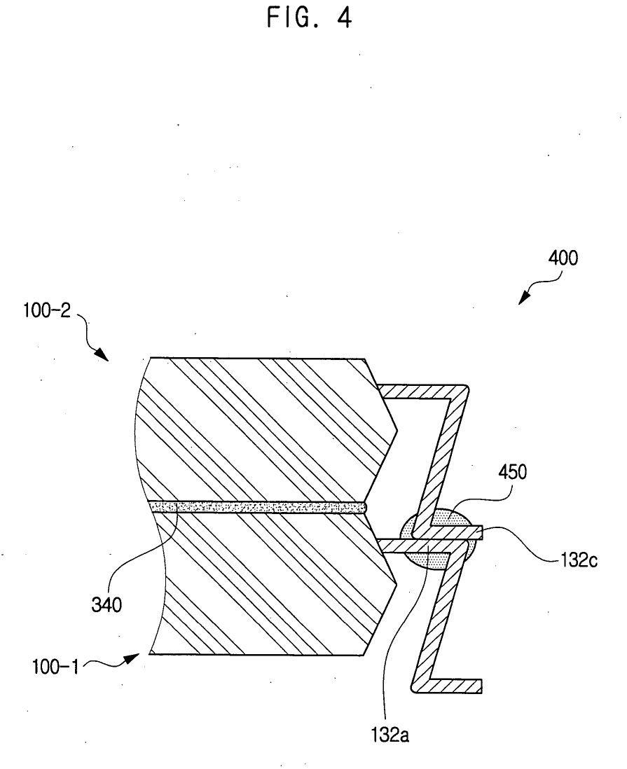

FIG. 4 is a partial cross-sectional view of a package stacking structure 400 in accordance with still another example embodiment of the present invention.

Referring to FIG. 4, the package stacking structure 400 may have a first semiconductor package 100-1, a second semiconductor package 100-2 and a bonding member 450.

The bonding member 450 may provide a secure electrical connection between the first semiconductor package 100-1 and the second semiconductor package 100-2. For example, the bonding member 450 may mechanically bond and electrically connect a first portion 132a of the first semiconductor package 100-1 to a third portion 132c of the second semiconductor package 100-2. The bonding member 450 may be formed from materials having mechanical adhesion and electrical conductivity, for example, a solder, a conductive epoxy, or a conductive adhesive tape. A package stacking method using the bonding member 450 is described below.

Package Stacking Method

A package stacking method may comprise fabricating the first semiconductor package 100-1 and the second semiconductor package 100-2, stacking the second semiconductor package 100-2 on the first semiconductor package 100-1 such that the third portion 132c of the second semiconductor package 100-2 may be located on the first portion 132a of the first semiconductor package 100-1, and electrically connecting the first portion 132a of the first semiconductor package 100-1 to the third portion 132c of the second semiconductor package 100-2.

The electrical connection of the first and second semiconductor packages 100-1 and 100-2 may use the bonding member 450, for example a solder, a conductive epoxy, or a conductive adhesive tape. The bonding member 450 may be provided on the first portion 132a of the first semiconductor package 100-1 before a package stacking process. Alternatively, the bonding member 450 may be provided on the first portion 132a of the first semiconductor package 100-1 and the third portion 132c of the second semiconductor package 100-2 after a stacking process.

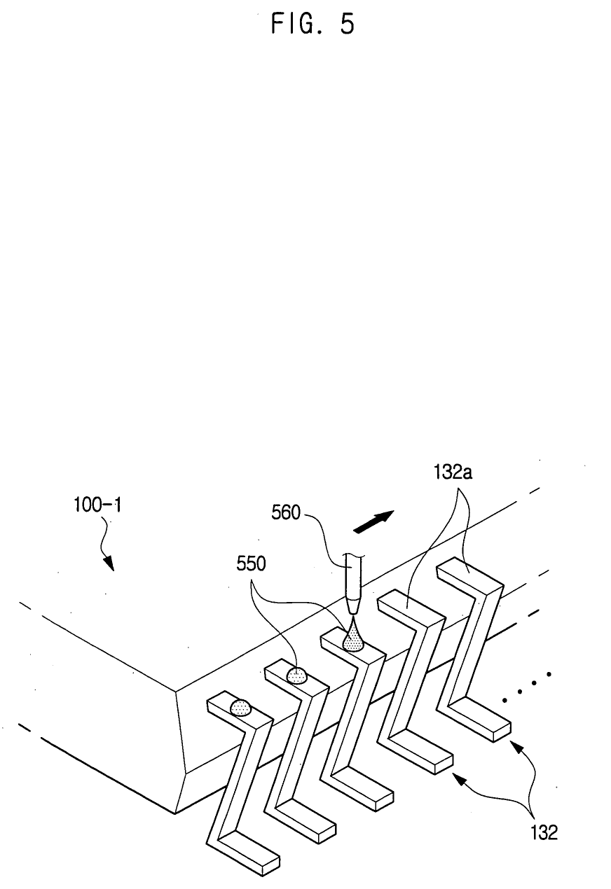

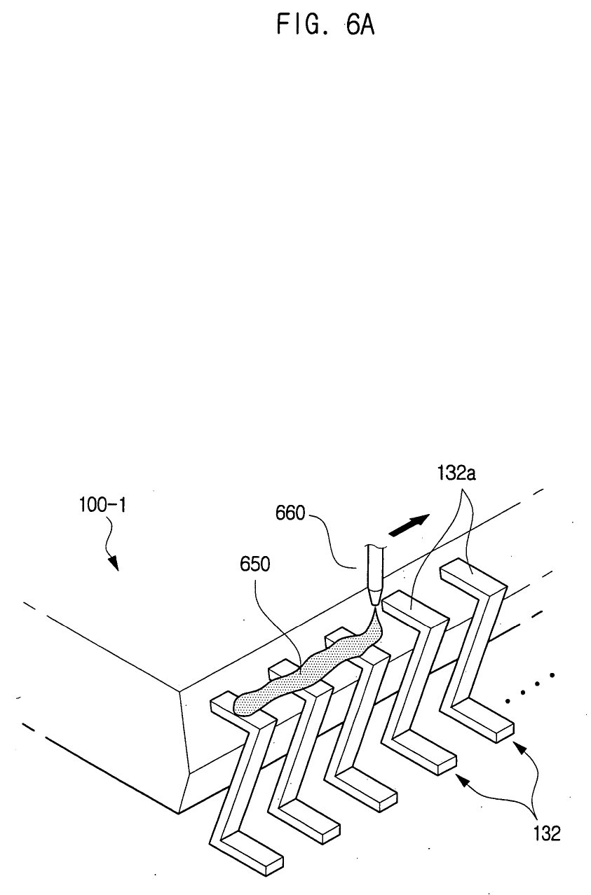

FIG. 5 is a perspective view of a package stacking method in accordance with an example embodiment of the present invention. This example embodiment shows the use of a solder 550 as a bonding member.

Referring to FIG. 5, the melted solder 550 may be applied to the first portion 132a of the first semiconductor package 100-1 before a package stacking process. The melted solder 550 may be applied to the first portion 132a of each outer lead 132 separately, using a typical application apparatus 560. The melted solder 550 may include Sn/Ag/Cu having a constitution by weight of 96.5/3/0.5 and a melting point of 217° C., and Sn/Pb having a weight constituent rate of 63/37 and a melting point of 183° C.

The melted solder 550 may be replaced by a liquid conductive epoxy having a sufficient viscosity to function as a bond member described above. In this case, the package stacking method may further comprise a curing process before and after a package stacking process. In alternative embodiments, the solder 550 or the liquid conductive epoxy may be applied after a package stacking process. In alternative embodiments, the solder 550 or the liquid conductive epoxy may be continuously applied to the outer leads 132.

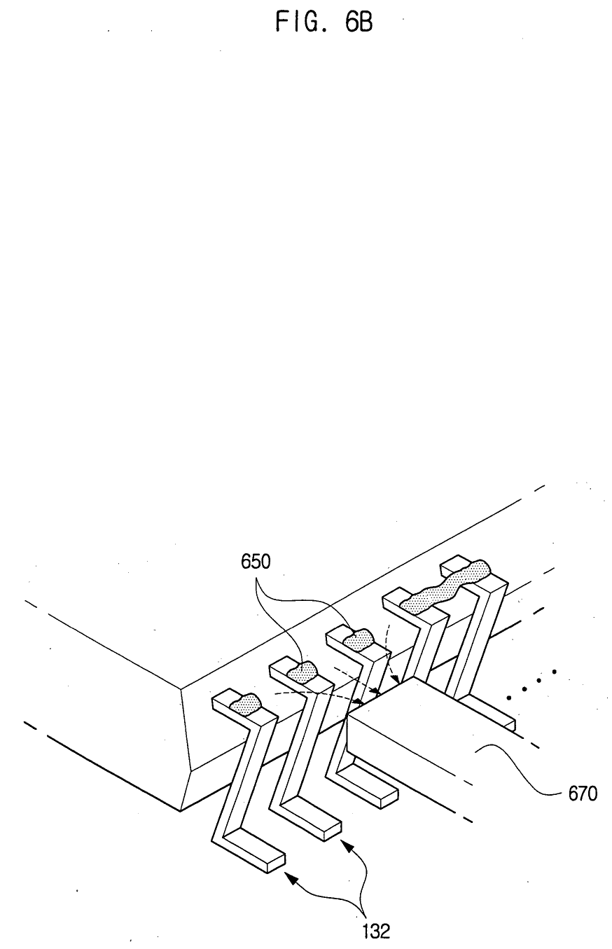

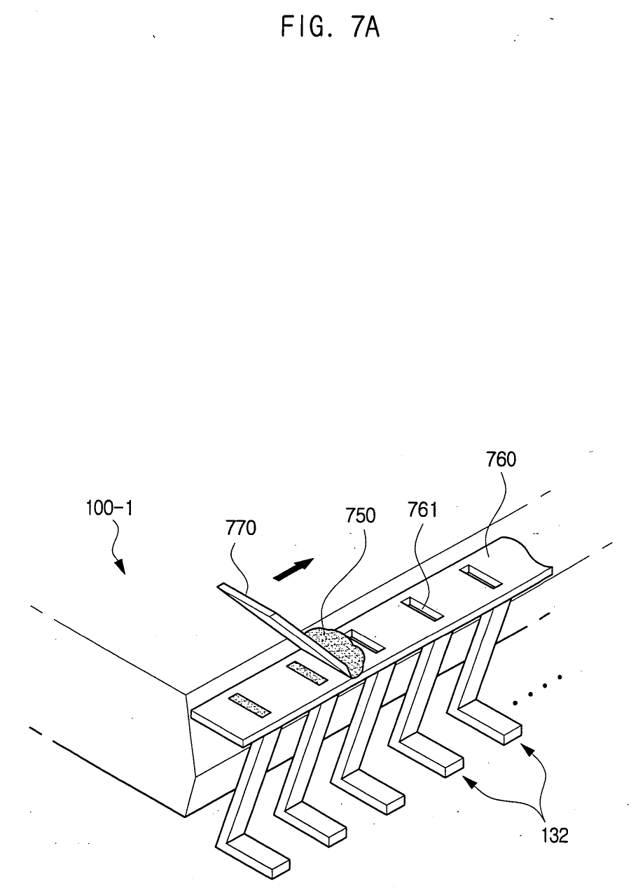

FIGS. 6A and 6B are perspective views of a package stacking method in accordance with another example embodiment of the present invention.

Referring to FIG. 6A, a melted solder 650 or a liquid conductive epoxy may be continuously applied to first portions 132a of outer leads 132 using an application apparatus 660. After the melted solder 650 or the liquid conductive epoxy may be soft-cured, a second semiconductor package (not shown) may be stacked on a first semiconductor package 100-1. Illustration of the second semiconductor package is omitted for clearer illustration, it being understood that the second semiconductor package would be positioned for engagement as described above, e.g., as illustrated in FIG. 3.

Referring to FIG. 6B, unnecessary solder or epoxy between the outer leads 132 may be removed using a suction apparatus 670 or a fan device known to one skilled in the art. For example, the suction apparatus 670 may remove the unnecessary solder or epoxy, e.g., under a high temperature atmosphere and vacuum suction. The fan device may blow high temperature air to remove the unnecessary solder or epoxy. The remaining solder or epoxy may be then completely cured.

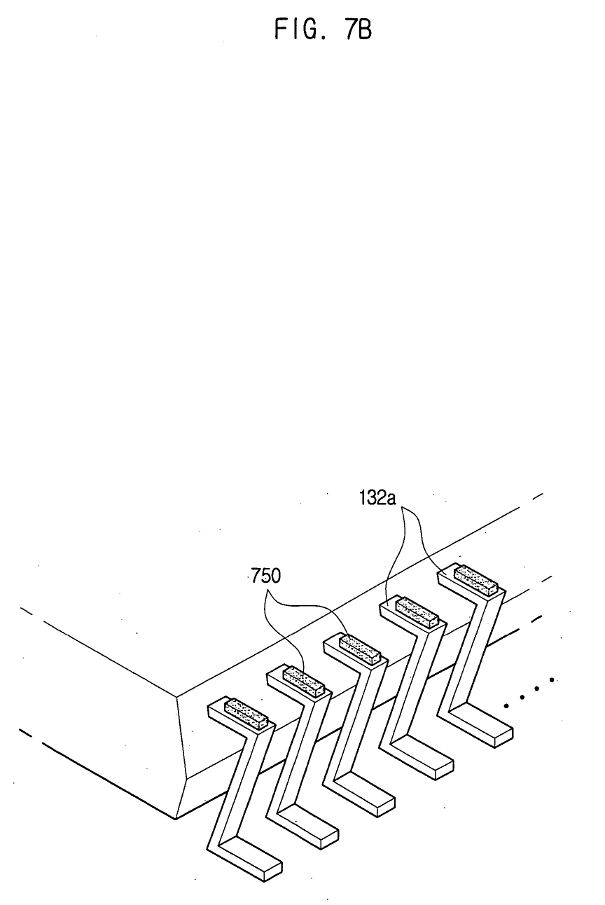

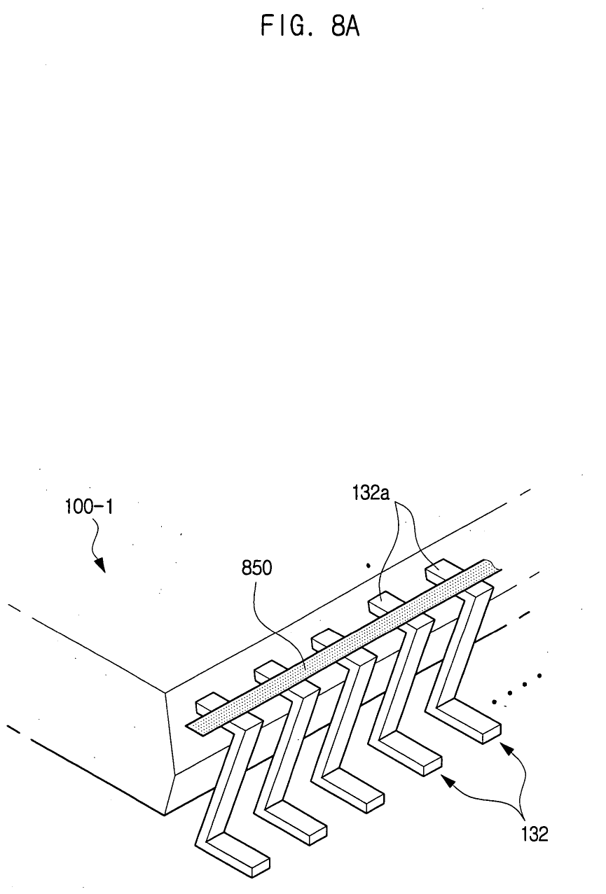

FIGS. 7A and 7B are perspective views of a package stacking method in accordance with yet another example embodiment of the present invention.

This example embodiment shows the use of a solder paste 750 as a bonding member. The solder paste 750 may be a mixture of a powder type solder and a liquid type flux.

Referring to FIG. 7A, the solder paste 750 may be applied to a first portion 132a of outer leads 132 using a screen printing method. For example, a stencil 760 having grooves 761 may be placed upon the outer leads 132. The grooves 761 may be arranged corresponding to the first portions 132a of the outer leads 132. The solder paste 750 may be applied into the grooves 761 of the stencil 760 using, for example, a squeezer 770. The stencil 760 may be removed. After a second semiconductor package (not shown) is stacked in place, an infrared reflow process may be performed.

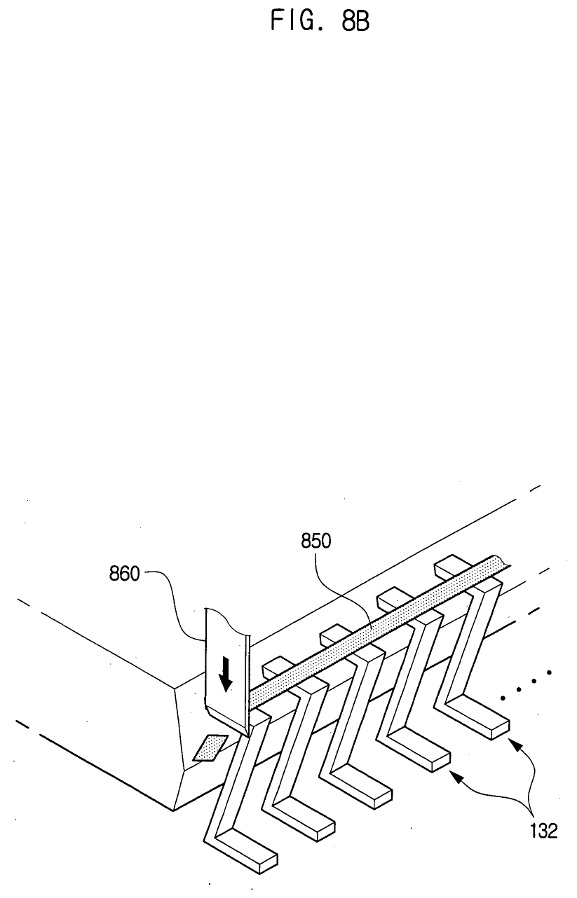

FIGS. 8A and 8B are perspective views of a package stacking method in accordance with still another example embodiment of the present invention. This example embodiment shows the use of a conductive adhesive tape 850 as a bonding member.

Referring to FIG. 8A, the conductive adhesive tape 850 may be attached to outer leads 132.

Referring to FIG. 8B, unnecessary portions of the adhesive tape 850 between the outer leads 132 may be removed using a cutter 860.

In accordance with the example embodiments of the present invention, a semiconductor package may have Z-shaped outer leads. A package stacking structure and method may be incorporated using the semiconductor packages having Z-shaped outer leads. The Z-shaped outer leads of adjacent semiconductor packages in the package stacking structure may directly contact with each other, so that adjacent semiconductor packages may be mechanically and electrically coupled to each other. The use of the Z-shaped outer leads need not influence the total width of the semiconductor package and/or a package mounting area.

The package stacking structure of the present invention may be simple and stable, thereby eliminating the need of lead processing, e.g., manipulation, after a package characteristic or validation test. The resulting semiconductor package is thereby made useful in a package stacking structure and/or independently.

The package stacking method of embodiments of the present invention may allow an easy process at competitive manufacturing costs. The use of various bonding members may provide reliability in various applications.

Although example, non-limiting embodiments of the present invention have been described in detail, it will be understood that many variations and/or modifications of the basic inventive concepts, which may appear to those skilled in the art, will still fall within the spirit and scope of the example embodiments of the present invention as defined in the appended claims.

What is claimed is:

1. A semiconductor package comprising:
a package body including a first surface, a second surface, and side surfaces connecting the first surface and the second surface;
at least one integrated circuit chip within the package body; and
a leadframe including inner leads coupled to the integrated circuit chip and including outer leads coupled to the inner leads and extending from the package body, the outer leads each having a proximal portion, an intermediate portion and a distal portion, the proximal portion being proximal to the first surface and intermediate a first plane containing the first surface and a second plane containing the second surface, the distal portion being substantially parallel to the proximal portion and beyond the second plane in a direction from the first plane to the second plane, the intermediate portion connecting the proximal portion and the distal portion.

2. The package of claim 1, wherein the proximal portion is substantially parallel to the first plane.

3. The package of claim 1, wherein the intermediate portion is at an angle of about 90° or less to each of the proximal portion and the distal portion.

4. The package of claim 1, wherein each of the outer leads further includes a connecting portion coupling the inner lead to the associated proximal portion.

5. The package of claim. 1, wherein a first distance between an upper surface of the distal portion and the second plane is greater than a second distance between an upper surface of the proximal portion and the first plane.

6. The package of claim 1, further comprising a second semiconductor package corresponding to the first semiconductor package as set forth in claim 1, the distal portion of each outer lead of the second semiconductor package being located upon and electrically connected to the proximal portion of a corresponding one of the outer leads of the first semiconductor package.

7. The package of claim 6, wherein the proximal portion of each outer lead is substantially parallel to the first surface of the corresponding package body in each of the first and second semiconductor packages.

8. The package of claim 6, wherein the intermediate portion of each outer lead is at an angle of substantially 90° or less to the proximal portion and the distal portion in each of the first and second semiconductor packages.

9. The package of claim 6, wherein each outer lead of at least one of the first and second semiconductor packages further includes a connecting portion coupling the inner leads thereof to the first portion of the outer lead thereof.

10. The package of claim 6, wherein the distal portions of the second semiconductor package are in contact with corresponding ones of the proximal portions of the first semiconductor package.

11. The package of claim 6, further comprising a bonding member mechanically and electrically coupling the distal portions of the second semiconductor package to corresponding ones of the proximal portions of the first semiconductor package.

12. The package of claim 6, wherein a first distance between an upper surface of each of the distal portions and the second plane is greater than a second distance between an upper surface of each of the proximal portions and the first plane in each of the first and second semiconductor packages.

13. The package of claim 12, further comprising an adhesive layer of a given thickness between the package body of the first semiconductor package and the package body of the second semiconductor package, the sum of the second distance and the given thickness being substantially equal to the first distance.

14. The package of claim 6, further comprising an adhesive layer provided between the package body of the first semiconductor package and the package body of the second semiconductor package.

15. The package of claim 1, wherein the intermediate portion connecting the proximal portion and the distal portion are in non-parallel relation thereto.

16. A semiconductor package stacking method comprising:
fabricating first and second semiconductor packages, each semiconductor package having a first surface and a second surface opposite thereto, each semiconductor package including outer leads having a proximal portion, an intermediate portion, and a distal portion, each proximal portion being substantially parallel to the associated distal portion, each proximal portion being intermediate a first plane containing the first surface of the associated semiconductor package and a second plane containing the second surface of the associated semiconductor package, each distal portion being beyond the second plane in a direction from the first plane toward the second plane;
stacking the second semiconductor package on the first semiconductor package with each of the distal portions of the second semiconductor package located upon corresponding ones of the proximal portions of the first semiconductor package; and
electrically coupling each of the proximal portions of the first semiconductor package to the corresponding ones of the distal portions of the second semiconductor package.

17. The method of claim 16, wherein the intermediate portion of each outer lead is at an angle of about 90° or less to the associated proximal portion and to the associated distal portion in each of the first and second semiconductor packages.

18. The method of claim 17, wherein the electrical coupling of the first and second semiconductor packages is by a bonding member.

19. The method of claim 18, wherein the bonding member includes a solder.

20. The method of claim 19, further comprising applying the solder to the proximal portions of the first semiconductor package before stacking the first and second semiconductor packages.

21. The method of claim 19, further comprising applying the solder to the proximal portions of the first semiconductor package and the distal portions of the second semiconductor package after stacking the first and second semiconductor packages.

22. The method of claim 19, further comprising screen printing a solder paste to the proximal portions of the first semiconductor package before stacking the first and second semiconductor packages.

23. The method of claim 18, wherein the bonding member includes a conductive epoxy.

24. The method of claim 23, further comprising applying the conductive epoxy to the proximal portions of the first semiconductor package and the distal portions of the second semiconductor package after stacking the first and second semiconductor packages.

25. The method of claim 23, further comprising applying the conductive epoxy to the first portion of the first semiconductor package before stacking the first and second semiconductor packages.

26. The method of claim 18, wherein the bonding member includes a conductive adhesive tape.

27. The method of claim 26, further comprising attaching the conductive adhesive tape to the proximal portions of the first semiconductor package before stacking the first and second semiconductor packages.

28. A semiconductor package comprising:
a package body including a first surface, a second surface, and side surfaces connecting the first surface and the second surface;
at least one integrated circuit chip within the package body; and
a leadframe including outer leads electrically coupled to the integrated circuit chip, each outer lead each having a proximal portion and a distal portion, the proximal portion being located a first distance from a first plane containing the first surface and intermediate the first plane and a second plane containing the second surface, the distal portion being substantially parallel and non-coplanar to the proximal portion and located a second distance from the second plane in a direction from the first plane toward the second plane.

29. The package of claim 28, wherein the at least one of the proximal portion and the distal portion is substantially parallel to at least one of the first and second planes.

30. The package of claim 28, wherein the outer leads each assume a generally Z-shape.

31. The package of claim 28, wherein each proximal portion is vertically aligned relative to the associated distal portion in reference to a vertical axis normal to at least one of the first and second planes.
